(19) United States
(12) Patent Application Publication
(10) Pub. No.: US 2021/0076537 A1
(43) Pub. Date: Mar. 11, 2021

(54) HEAT DISSIPATION MECHANISM FOR ELECTRONIC APPARATUSES

(71) Applicant: LENOVO (SINGAPORE) PTE. LTD., SINGAPORE (SG)

(72) Inventors: Tsutomu Chonan, Kanagawa (JP); Shogo Akiyama, Kanagawa (JP); Hiroshi Yamazaki, Kanagawa (JP)

(21) Appl. No.: 17/006,218

(22) Filed: Aug. 28, 2020

(30) Foreign Application Priority Data
Sep. 5, 2019 (JP) 2019-162115

(51) Int. Cl. H05K 7/20

(52) U.S. Cl. CPC H05K 7/20472

(57) ABSTRACT

A heat dissipation mechanism is provided. The heat dissipation mechanism includes a heat receiving plate and a heat transport member. The heat receiving plate includes a heat receiving surface surrounded by a recessed portion. The heat receiving surface is to be in contact with a heat transfer region of an electronic component in order to receive heat generated by the electronic component while the recessed portion receives at least one corner of the heat transfer region when viewed from a direction perpendicular to the heat receiving surface. The heat transport member transfers heat away from the heat receiving plate.

### PRIORITY CLAIM

The present application claims benefit of priority under 35 U.S.C. §§ 120, 365 to the previously filed Japanese Patent Application No. JP2019-162115 with a priority date of Sep. 5, 2019, which is incorporated by reference herein.

### TECHNICAL FIELD

The present invention relates to heat dissipation mechanisms in general, and in particular to a heat dissipation mechanism for an electronic apparatus.

### BACKGROUND

An electronic apparatus, such as a laptop personal computer (laptop PC), may be equipped with a heat dissipation mechanism to discharge heat generated by electronic components located within a chassis. Electronic components that generate a large amount of heat include, for example, a central processing unit (CPU) and a graphics processing unit (GPU).

A heat dissipation mechanism may include a metallic heat receiving plate and a heat transport member such as a heat pipe. The heat receiving plate is in contact with electronic components, such CPUs and GPUs, in order to receive heat from the electronic components. The heat transport member transports the heat from the heat receiving plate to a heat dissipater such as a heat sink, heat dissipation fin, etc.

The heat dissipation mechanism may be in a slightly tilted posture with respect to any electronic component due to variations in the dimensions of electronic components. Because an electronic component is in contact with the heat receiving plate in a narrow area, there is a possibility that a large force intensively acts locally on the electronic component by the heat receiving plate.

Consequently, it would be desirable to provide an improved heat dissipation mechanism that can reduce the intensive force acted locally on an electronic component in contact with a heat receiving plate.

### SUMMARY

In accordance with an embodiment of the present disclosure, a heat dissipation mechanism includes a heat receiving plate and a heat transport member. The heat receiving plate includes a heat receiving surface surrounded by a recessed portion. The heat receiving surface is to be in contact with a heat transfer region of an electronic component in order to receive heat generated by the electronic component while the recessed portion receives at least one corner of the heat transfer region when viewed from a direction perpendicular to the heat receiving surface. The heat transport member transfers heat away from the heat receiving plate.

All features and advantages of the present disclosure will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a perspective view of a heat dissipation mechanism according to a first embodiment;

FIG. 2 is an enlarged view of the heat dissipation mechanism from FIG. 1;

FIG. 3 is a side view of the heat dissipation mechanism from FIG. 1;

FIG. 4 is a top view of a heat receiving plate of the heat dissipation mechanism from FIG. 1;

FIG. 5 is a cross-sectional view of a heat receiving plate of the heat dissipation mechanism from FIG. 1;

FIG. 6 is a perspective view of a heat dissipation mechanism according to a second embodiment;

FIG. 7 is a side view of the heat dissipation mechanism from FIG. 6;

FIG. 8 is a top view of a heat receiving plate of the heat dissipation mechanism from FIG. 6;

FIG. 9 is a cross-sectional view of the heat receiving plate from FIG. 8; and

FIG. 10 is a cross-sectional view of a modified example of the heat receiving plate from FIG. 8.

### DETAILED DESCRIPTION

### I. First Embodiment

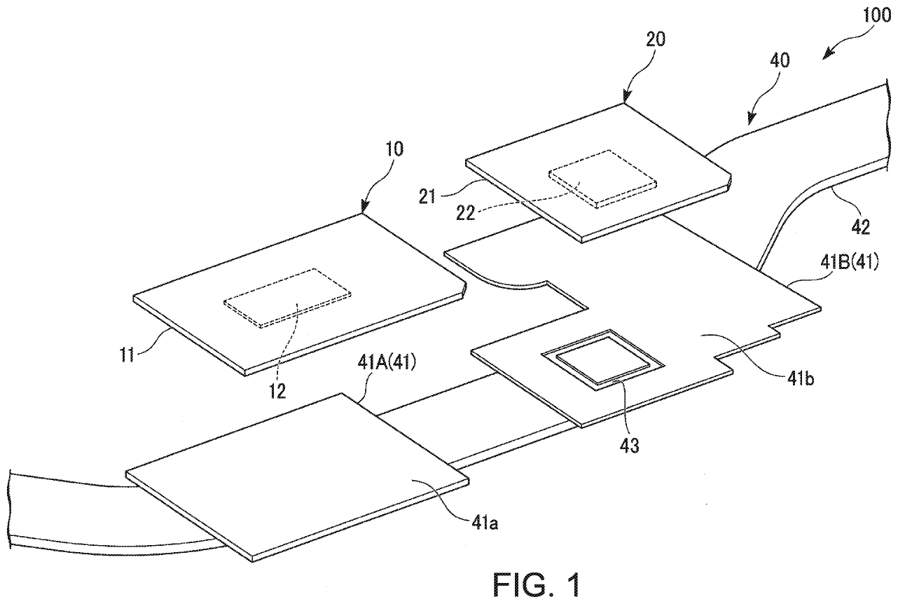

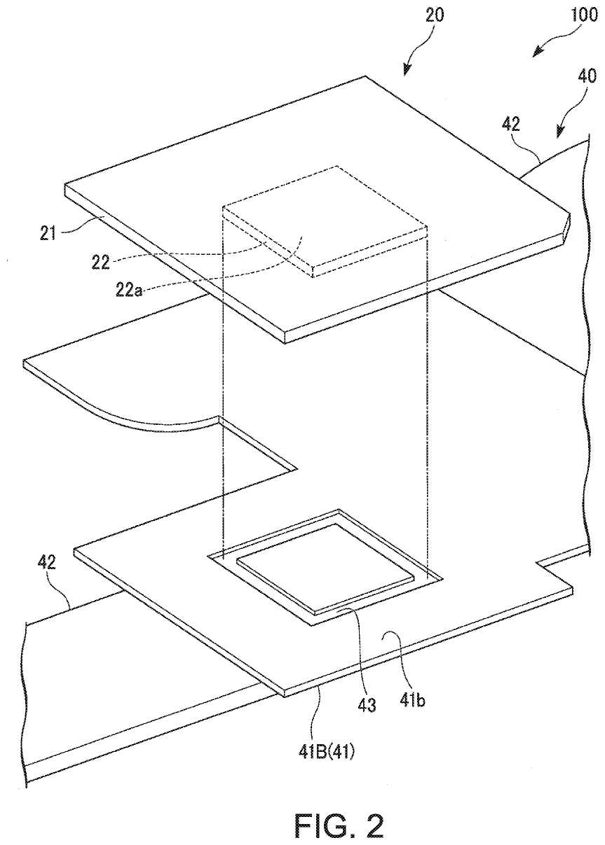

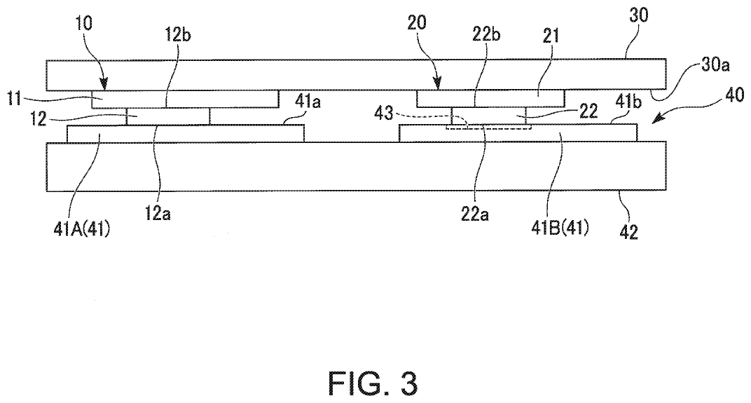

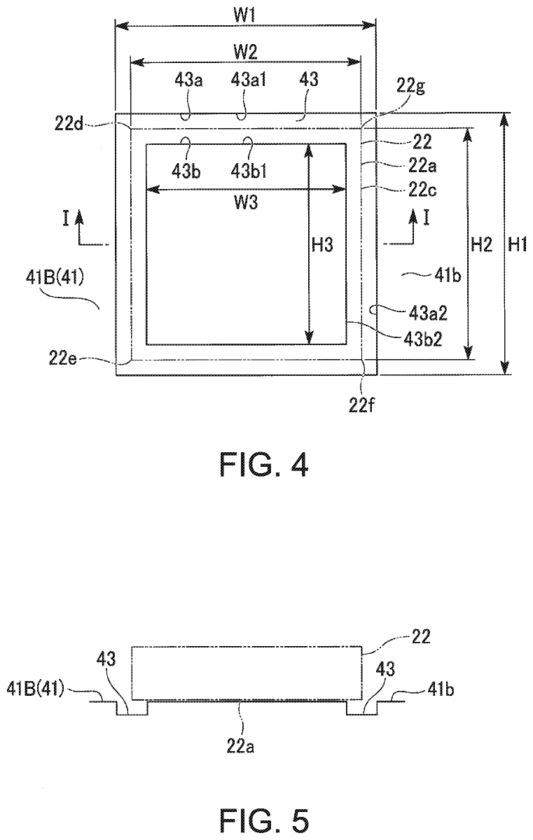

FIG. 1 is a perspective view of a heat dissipation mechanism 40 according to a first embodiment. FIG. 2 is an enlarged view of the heat dissipation mechanism 40. FIG. 3 is a side view of the heat dissipation mechanism 40. FIG. 4 is a top view of a heat receiving plate 41 of the heat dissipation mechanism 40. FIG. 5 is a cross-sectional view of the heat receiving plate 41 taken along the line I-I of FIG. 4.

As illustrated in FIG. 1, an electronic apparatus 100 includes a central processing unit 10 (first electronic component), a graphics processing unit 20 (second electronic component), a motherboard 30 (main board), and the heat dissipation mechanism 40.

The central processing unit (CPU) 10, the graphics processing unit (GPU) 20, the motherboard 30, and the heat dissipation mechanism 40 are housed in a chassis (not illustrated). The electronic apparatus 100 may be a laptop personal computer (laptop PC), a workstation, a server, etc.

The CPU 10 is a processor that executes application programs to perform general processing. The CPU 110 includes a board 11 and a semiconductor chip 12. The board 11 is a printed circuit board (PCB) for example. A memory, a capacitor, and the like may be also mounted on the board 11. The semiconductor chip 12 is provided on one surface of the board 11. The semiconductor chip 12 is formed in a rectangular plate shape.

As illustrated in FIG. 3, a first principal surface 12a of the semiconductor chip 12 is a heat transfer region for transferring heat to the heat receiving plate 41 (first heat receiving plate 41A). The first principal surface 12a is called a heat transfer region 12a, The heat transfer region 12a has a rectangular shape. The heat transfer region 12a is a surface opposite to a second principal surface 12b that faces the board 11. The heat transfer region 12a is in contact with the heat receiving plate 41 (the first heat receiving plate 41A) in a face-to-face manner to transfer the heat of the semiconductor chip 12 to the heat receiving plate 41 (the first heat receiving plate 41A).

As illustrated in FIG. 1, the GPU 20 is a processor that performs a drawing process. The GPU 20 includes a board 21 and a semiconductor chip (die) 22. The board 21 is a printed circuit board (PCB) for example. A memory, a capacitor, and the like may be also mounted on the board 21.

The semiconductor chip 22 is provided on one surface of the board 21. The semiconductor chip 22 is formed in a rectangular plate shape.

As illustrated in FIG. 3, a first principal surface 22a of the semiconductor chip 22 is a heat transfer region for transferring heat to the heat receiving plate 41 (second heat receiving plate 41B). The first principal surface 22a is called a heat transfer region 22a. The heat transfer region 22a has a rectangular shape. The heat transfer region 22a is a surface opposite to a second principal surface 22b that faces the board 21. The heat transfer region 22a is in contact with the heat receiving plate 41 (the second heat receiving plate 41B) in a face-to-face manner to transfer the heat of the semiconductor chip 22 to the heat receiving plate 41 (the second heat receiving plate 41B).

As illustrated in FIG. 4, the four corners of the heat transfer region 22a are respectively called a first corner 22d, a second corner 22e, a third corner 22f, and a fourth corner 22g. The first corner 22d and the second corner 22e are located closer to the CPU 10 compared to the third corner 22f and the fourth corner 22g.

As illustrated in FIG. 3, the CPU 10 and the GPU 20 are mounted on a first principal surface 30a of the shared motherboard 30.

As illustrated in FIG. 1, the heat dissipation mechanism 40 includes the heat receiving plates 41 and a heat pipe (heat transport member) 42. Each of the heat receiving plates 41 is made of metal such as copper and aluminum.

As illustrated in FIG. 3, the heat receiving plates 41 are installed so that heat can be transferred to the heat pipe 42. The heat receiving plates 41 are in contact with the heat pipe 42 to be thermally coupled to the heat pipe 42. The heat receiving plates 41 are installed at different positions in a length direction of the heat pipe 42.

One surface of the one heat receiving plate 41 (the first heat receiving plate 41A) of the two heat receiving plates 41 is called a heat receiving surface 41a. The first heat receiving plate 41A is overlaid on the CPU 10. The heat receiving surface 41a is in contact with the heat transfer region 12a of the CPU 10. As a result, the first heat receiving plate 41A is thermally coupled to the CPU 10.

One surface of the other heat receiving plate 41 (the second heat receiving plate 41B) of the two heat receiving plates 41 is called a heat receiving surface 41b. The second heat receiving plate 41B is overlaid on the GPU 20. The heat receiving surface 41b is in contact with the heat transfer region 22a of the GPU 20. As a result, the second heat receiving plate 41B is thermally coupled to the GPU 20.

As illustrated in FIGS. 2 and 4, a recessed portion 43 is formed on the heat receiving surface 41b of the second heat receiving plate 41B. The recessed portion 43 is a rectangular groove when viewed from a direction perpendicular to the heat receiving surface 41b. The groove width of the recessed portion 43 is uniform. In addition, viewing from the direction perpendicular to the heat receiving surface 41b is called “planar view”.

As illustrated in FIG. 4, a first length W1 of an outer peripheral edge 43a of the recessed portion 43 is greater than a first length W2 of the heat transfer region 22a of the GPU 20. A first length W3 of an inner peripheral edge 43b of the recessed portion 43 is smaller than the first length W2 of the heat transfer region 22a. The first length W1 of the outer peripheral edge 43a is the length of a first side 43a1 of the rectangular outer peripheral edge 43a. The first length W3 of the inner peripheral edge 43b is the length of a first side 43b1 of the rectangular inner peripheral edge 43b.

A second length H1 of the outer peripheral edge 43a of the recessed portion 43 is greater than a second length H2 of the heat transfer region 22a of the GPU 20. A second length H3 of the inner peripheral edge 43b of the recessed portion 43 is smaller than the second length H2 of the heat transfer region 22a. The second length H1 of the outer peripheral edge 43a is the length of a second side 43a2 adjacent to the first side 43a1 of the outer peripheral edge 43a. The second length H3 of the inner peripheral edge 43b is the length of a second side 43b2 adjacent to the first side 43b1 of the inner peripheral edge 43b.

In planar view, a peripheral edge 22c of the heat transfer region 22a is located inside the outer peripheral edge 43a and outside the inner peripheral edge 43b. For that reason, the recessed portion 43 contains the whole of the peripheral edge 22c of the heat transfer region 22a. The corners 22d to 22g of the heat transfer region 22a are contained within the recessed portion 43 in planar view.

As illustrated in FIG. 5, the shape of a cross section perpendicular to the length direction of the recessed portion 43 is a rectangular shape, for example. Note that the cross-sectional shape of the recessed portion is not particularly limited, and thus may be a semicircular shape, a V shape, etc.

Grease may be filled between the GPU 20 and the heat receiving plate 41 (the second heat receiving plate 41B). Grease may be filled between the CPU 10 and the heat receiving plate 41 (the first heat receiving plate 41A).

As illustrated in FIG. 1, the heat pipe 42 is configured of a tubular body in which an enclosed space is formed. The heat pipe 42 is made of metal such as copper and aluminum. Working fluid is flowably enclosed in the enclosed space inside the heat pipe 42. A wick is provided inside the heat pipe 42, for example.

The heat pipe 42 is connected to a heat dissipation unit (not illustrated) for example. The heat dissipation unit includes a heat sink and a heat dissipation fan, for example. The heat sink is connected to the heat pipe 42. The heat dissipation fan cools the heat sink by blowing air.

As illustrated in FIG. 3, because the CPU 10 and the GPU 20 are provided on the shared motherboard 30, their positions or postures may be difficult to be independently adjusted. For that reason, when the position and posture of the CPU 10 is set so that the CPU 10 and the first heat receiving plate 41A have contact with each other without any gap, the GPU 20 may be in a slightly tilted posture with respect to the second heat receiving plate 41B due to variations in component dimensions, curvature deformation of the motherboard 30, etc.

As illustrated in FIG. 4, in the heat dissipation mechanism 40, because the recessed portion 43 is formed on the heat receiving surface 41b of the second heat receiving plate 41B, the peripheral edge 22c of the heat transfer region 22a does not abut on the heat receiving surface 41b. For that reason, even if the GPU 20 is in a tilted posture, a force can be suppressed from intensively acting on the peripheral edge 22c of the heat transfer region 22a. Therefore, a damage to the GPU 20 is hard to occur.

In the heat dissipation mechanism 40, because the recessed portion 43 is formed on the heat receiving surface 41b, it is easier to secure surface contact between the heat transfer region 22a and the heat receiving surface 41b, compared to the case without the recessed portion 43. Therefore, it is possible to improve heat transfer efficiency between the heat transfer region 22a and the heat receiving surface 41b.

As the first comparative form, it is assumed that a heat dissipation mechanism (not illustrated) includes a heat receiving plate whose heat receiving surface does not have a recessed portion. In this heat dissipation mechanism, when the heat transfer region of an electronic component is tilted, the heat transfer region may have contact with the heat receiving surface only at one corner and thus a large force may intensively act on this corner.

As the second comparative form, it is assumed that the heat dissipation mechanism of the first comparative form further includes a soft material layer provided between the electronic component and the heat receiving plate. In the second comparative form, a force applied to the electronic component can be reduced by the soft material layer, but heat transfer characteristics between the electronic component and the heat receiving plate are decreased.

In the heat dissipation mechanism 40, the recessed portion 43 is formed in a groove shape containing the entire peripheral edge of the heat transfer region 22a in planar view. For that reason, regardless of the inclination direction of the GPU 20, a force can be suppressed from concentrating locally on the heat transfer region 22a in contact with the heat receiving surface 41b.

### II. Second Embodiment

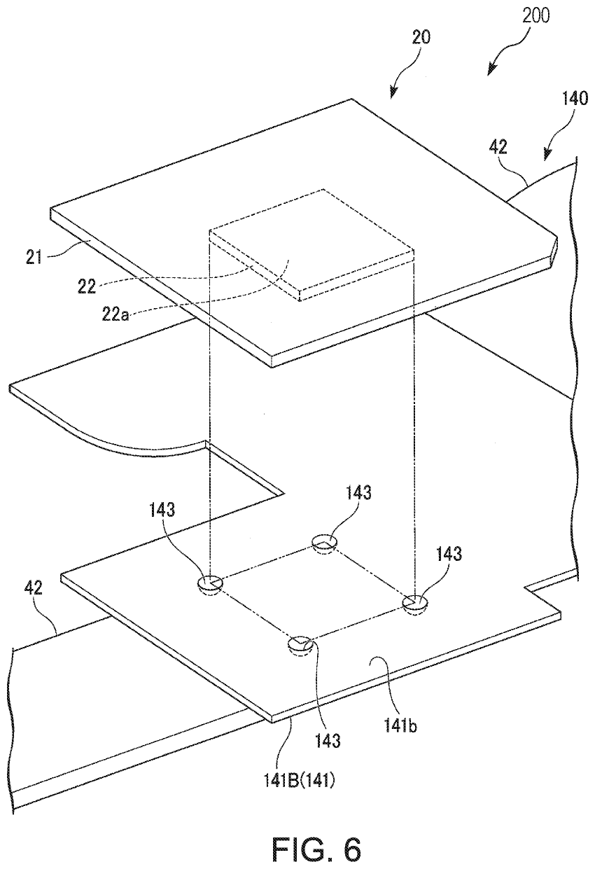

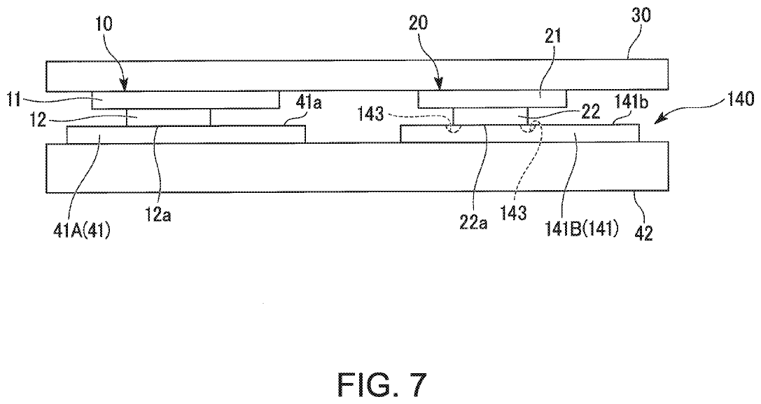

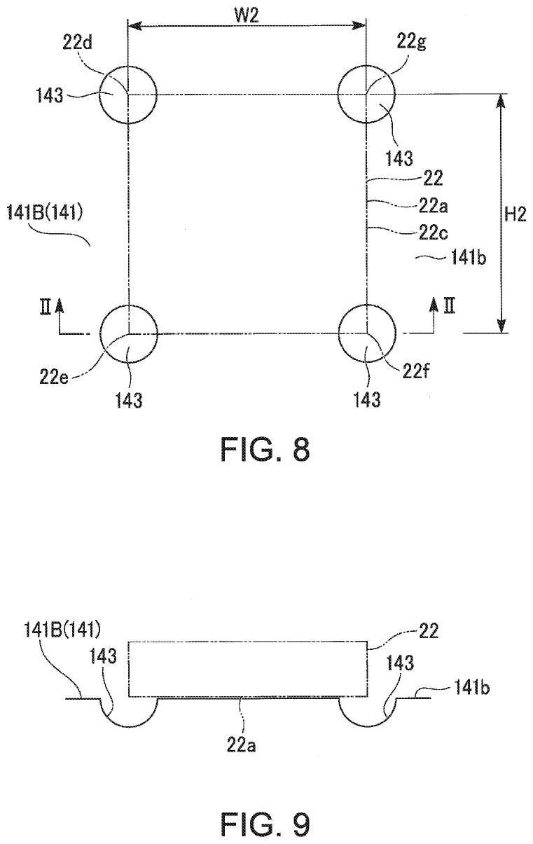

FIG. 6 is a perspective view of a heat dissipation mechanism 140 according to a second embodiment. FIG. 7 is a side view of the heat dissipation mechanism 140. FIG. 8 is a top view of a heat receiving plate 141 of the heat dissipation mechanism 140. FIG. 9 is a cross-sectional view of the heat receiving plate 141 of the heat dissipation mechanism 140. FIG. 9 illustrates a cross-sectional view taken along the line of FIG. 8. Herein, the same components as those in the first embodiment are designated by the same reference numbers and their descriptions will be omitted.

As illustrated in FIG. 6, an electronic apparatus 200 according to the second embodiment has the shape of recessed portions 143 that is different from the shape of the recessed portion 43 illustrated in FIG. 2.

The heat dissipation mechanism 140 includes the heat receiving plate 41 (the first heat receiving plate 41A) (see FIG. 7), the heat receiving plate 141 (second heat receiving plate 141B), and the heat pipe 42.

As illustrated in FIG. 7, the heat receiving plate 141 is installed so that heat can be transferred to the heat pipe 42. The heat receiving plate 141 is thermally coupled to the heat pipe 42 by having contact with the heat pipe 42. The heat receiving plate 41 (the first heat receiving plate 41A) and the heat receiving plate 141 (the second heat receiving plate 141B) are installed at different positions in the length direction of the heat pipe 42.

One surface of the second heat receiving plate 141B is called a heat receiving surface 141b. The second heat receiving plate 141B is overlaid on the GPU 20. The heat receiving surface 141b is in contact with the first principal surface 22a (the heat transfer region 22a) of the GPU 20. As a result, the second heat receiving plate 141B is thermally coupled to the GPU 20.

As illustrated in FIGS. 6 and 8, the plurality (e.g., four) of recessed portions 143 is formed on the second heat receiving plate 141B. Each of the recessed portions 143 is a circular recessed portion in planar view. The four recessed portions 143 are formed apart from each other. The four recessed portions 143 respectively contain the corners 22d to 22g of the heat transfer region 22a in planar view. It is preferable that the centers of the recessed portions 143 are respectively located at the corners 22d to 22g in planar view.

Note that the shape of the recessed portion in planar view is not limited to a circular shape and may be a rectangular shape, an oval shape, etc.

As illustrated in FIG. 9, the shape of a cross section of the recessed portion 143 perpendicular to the heat receiving surface 141b is a semicircular shape, for example. Note that the cross-sectional shape of the recessed portion is not particularly limited, and thus may be a rectangular shape, a V shape, etc.

In the heat dissipation mechanism 140, because the recessed portions 143 are formed on the heat receiving surface 141b of the second heat receiving plate 141B, the corners 22d to 22g of the heat transfer region 22a do not abut on the heat receiving surface 141b. For that reason, even if the (IPU 20 is in a tilted posture, a force can be suppressed from intensively acting locally on the heat transfer region 22a. Therefore, a damage to the (IPU 20 is hard to occur.

In the heat dissipation mechanism 140, because the recessed portions 143 are formed on the heat receiving surface 141b, it is easy to secure surface contact between the heat transfer region 22a and the heat receiving surface 141b. Therefore, it is possible to improve heat transfer efficiency between the heat transfer region 22a and the heat receiving surface 141b.

The recessed portions 143 can be more easily formed in comparison with a groove-shaped recessed portion because these are circular.

The specific configuration of the present invention is not limited to the above embodiments and also includes designs etc. without departing from the scope of the present invention. The configurations described in the above embodiments can be arbitrarily combined.

In the above embodiments, a laptop PC or the like has been exemplified as the electronic apparatus, but examples of the electronic apparatus also include a smart phone, a mobile phone unit, and the like.

The recessed portion 43 illustrated in FIG. 2 contains all the four corners 22d to 22g of the heat transfer region 22a, but the recessed portion may contain at least one of the four corners of the heat transfer region in planar view. For example, the recessed portion may contain the two corners 22d and 22e of the four corners 22d to 22g.

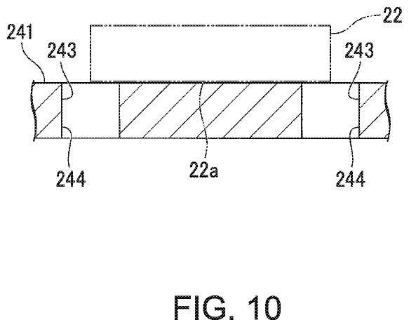

The recessed portion 43 illustrated in FIG. 2 and the recessed portions 143 illustrated in FIG. 6 are recessed portions that do not penetrate through the heat receiving plates 41 and 141, but these recessed portions may be formed by through-holes that penetrate through the heat receiving plates in the thickness direction. FIG. 10 is a cross-sectional view illustrating a heat receiving plate 241 corresponding to a modified example of the heat receiving plate 141. Herein, recessed portions 243 formed in the heat receiving plate 241 are formed by through-holes 244 that penetrate through the heat receiving plate 241 in the thickness direction.

The electronic apparatus 100 illustrated in FIG. 1 includes two electronic components, namely, the CPU 10 (the first electronic component) and the GPU 20 (the second electronic component), but the number of electronic components included in the electronic apparatus may be one or may be an arbitrary number of three or more. The number of the heat receiving plates is the same number as the number of the electronic components.

As has been described, the present invention provides a heat dissipation mechanism for electronic apparatuses.

While the invention has been particularly shown and described with reference to a preferred embodiment, it will be understood by those skilled in the art that various changes in form and detail may be made therein without departing from the spirit and scope of the invention.

What is claimed is:

1. A heat dissipation mechanism comprising:
a heat receiving plate includes a heat receiving surface surrounded by a recessed portion, wherein said heat receiving surface is to be in contact with a heat transfer region of an electronic component in order to receive heat generated by said electronic component while said recessed portion receives at least one corner of said heat transfer region when viewed from a direction perpendicular to said heat receiving surface; and
a heat transport member transfers heat away from said heat receiving plate-

1. The heat dissipation mechanism of claim 1, wherein said heat transfer region is in a rectangular shape.

3. The heat dissipation mechanism of claim 1, wherein said heat transfer region is in a square shape.

4. The heat dissipation mechanism of claim 1, wherein the surface area of said heat transfer region is smaller than the surface area of said heat transfer region.

1. The heat dissipation mechanism of claim 1, wherein said at least one corner of said heat transfer region overhangs said recessed portion.

6. The heat dissipation mechanism of claim 1, wherein said recessed portion is formed in a rectangular shape groove containing an entire peripheral edge of said heat transfer region when viewed from said direction perpendicular to said heat receiving surface.

7. The heat dissipation mechanism of claim 6, further comprising additional peripheral edges of said heat transfer region are contained by said recessed portion.

8. The heat dissipation mechanism of claim 1, wherein said recessed portion is formed in a semi-circular shape groove containing an entire peripheral edge of said heat transfer region when viewed from said direction perpendicular to said heat receiving surface.

9. The heat dissipation mechanism of claim 8, further comprising additional peripheral edges of said heat transfer region are contained by said recessed portion.

10. The heat dissipation mechanism of claim 1, wherein said electronic component is a central processing unit.

10. The heat dissipation mechanism of claim 10, further comprising a graphical processing unit.

12. The heat dissipation mechanism of claim 11, wherein said central processing unit and said graphical processing unit is mounted on a main board.
